(19) United States
(12) Patent Application Publication
(10) Pub. No.: US 2014/0184040 A1
(43) Pub. Date: Jul. 3, 2014

(54) ELECTRONIC DEVICE ENCLOSURE WITH HANDLE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: ZHAN-YANG LI, Shenzhen (CN)

(73) Assignees: HONG HAI PRECISION INDUSTRY CO., LTD., New Taipei (TW); HON FU JIN PRECISION INDUSTRY (ShenZhen) CO., LTD., Shenzhen (CN)

(21) Appl. No.: 14/028,907

(22) Filed: Sep. 17, 2013

(30) Foreign Application Priority Data
Dec. 29, 2012 (CN) 2012105893047

(51) Int. Cl. H05K 5/02

(52) U.S. Cl. CPC H05K 5/023; H05K 5/0221
USPC 312/223.1

(57) ABSTRACT

An electronic device enclosure includes a chassis, a covering secured to the chassis, a handle rotatably mounted to the chassis, and a latching member slidably mounted between the chassis and the covering member and comprising a hook, a resisting arm, and a pressing portion. The pressing portion extends out of the covering member. The handle defines a latching slot, which engages the hook. The resisting arm is elastically deformed to resist the handle. The pressing portion is operable to be pressed to slide the latching member relative to the chassis to disengage the hook from the latching slot, and then the resisting arm rebounds to open the handle, without pulling out the handle forcefully by hand.

### BACKGROUND

1. Technical Field

The present disclosure relates to a vending machine, and particularly to a electronic device with a handle.

2. Description of Related Art

In many electronic devices, such as servers and containers, heavy electronic modules, such as power supplies and fan modules, are secured in an enclosure. Generally, a handle is rotatably mounted to the enclosure by a rotating shaft for moving the enclosure conveniently. However, when moving the enclosure, the handle should be pulled out forcefully, which is inconvenient. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an electronic device enclosure.

FIG. 2 is similar to FIG. 1, but viewed from a different aspect.

FIG. 3 is an assembled, isometric view of the electronic device enclosure of FIG. 1, with a handle in a closed position.

FIG. 4 is a cross-sectional view taken along a line IV-IV of the electronic device enclosure of FIG. 3.

FIG. 5 is another assembled, isometric view of the electronic device enclosure of FIG. 1, with the handle in an open position.

FIG. 6 is a cross-sectional view taken along a line VI-VI of the electronic device enclosure of FIG. 5.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

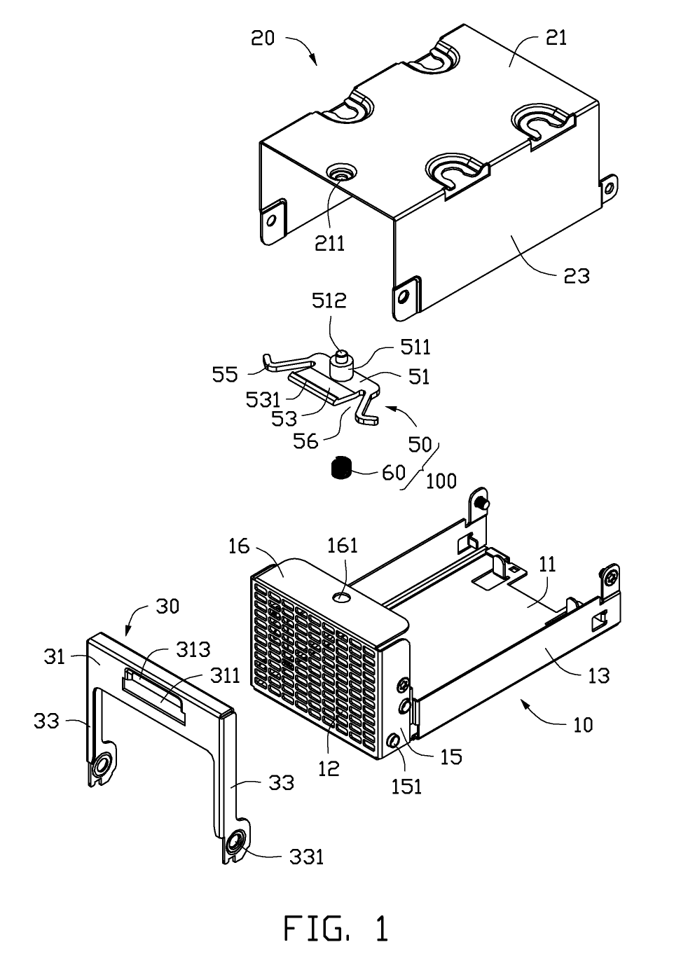

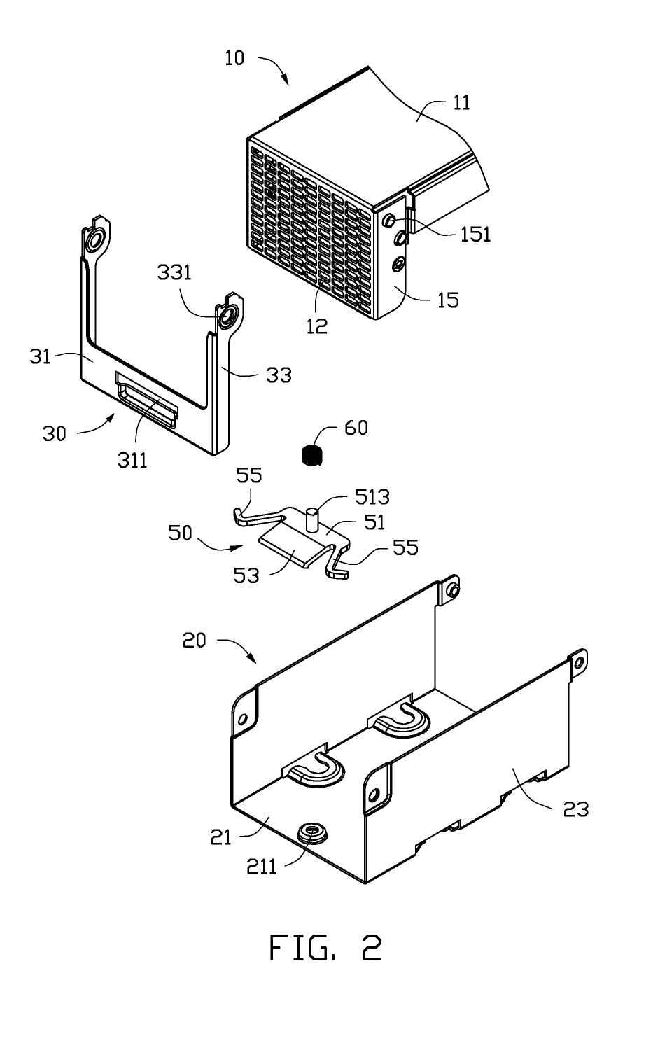

FIG. 1 and FIG. 2 show one embodiment of an electronic device enclosure for securing an electronic module (not shown). The electronic device enclosure includes a chassis 10, a covering member 20, a handle 30, and a securing assembly 100.

The chassis 10 includes a bottom plate 11, a front plate 12, and two side plates 13. The two side plates 13 are opposite to each other. In this embodiment, the bottom plate 11 is substantially perpendicular to the front plate 12 and the side plates 13, and the front plate 12 is substantially perpendicular to the side plates 13. A flange 15 extends from each of opposite side edges of the front plate 12, which is substantially perpendicular to bottom plate 11. A holding plate 16 extends from a top edge of the front plate 12, which is substantially parallel to bottom plate 11. The flange 15 is riveted with the two side plates 13. In this embodiment, the flange 15 is substantially parallel to each side plate 13, and the holding plate 16 is substantially perpendicular to bottom plate 11. A pivoting shaft 151 is located on the flange 15. The holding plate 16 defines a receiving hole 161.

The covering member 20 includes a top wall 21 and two sidewalls 23. The top wall 21 defines a through hole 211. In this embodiment, the top wall 21 is substantially perpendicular to each sidewall 23.

The handle 30 includes a mounting plate 31 and two rotating arms 33 connected to the mounting plate 31. The mounting plate 31 defines a latching slot 311 and a recess portion 313 communicating with the latching slot 311. Each rotating arm 33 defines a pivoting hole 331.

The securing assembly 100 includes a latching member 50 and a resilient member 60.

The latching member 50 includes a holding piece 51, a resilient piece 53, and two resisting arms 55 extending from the holding piece 51. A limiting post 511 extends from a top surface of the holding piece 51. A positioning post 513 extends from a bottom surface of the holding piece 51. A pressing portion 512 extends from the limiting post 511 for being received in the through hole 211. The resilient piece 53 extends obliquely from the holding piece 51. A hook 531 extends a distal end of the resilient member 53. A cutout 56 is defined between the resilient piece 53 and each resisting arm 55. In this embodiment, each resisting arm 55 is substantially “L” shaped.

In this embodiment, the resilient member 60 is a coiled spring and a compression spring.

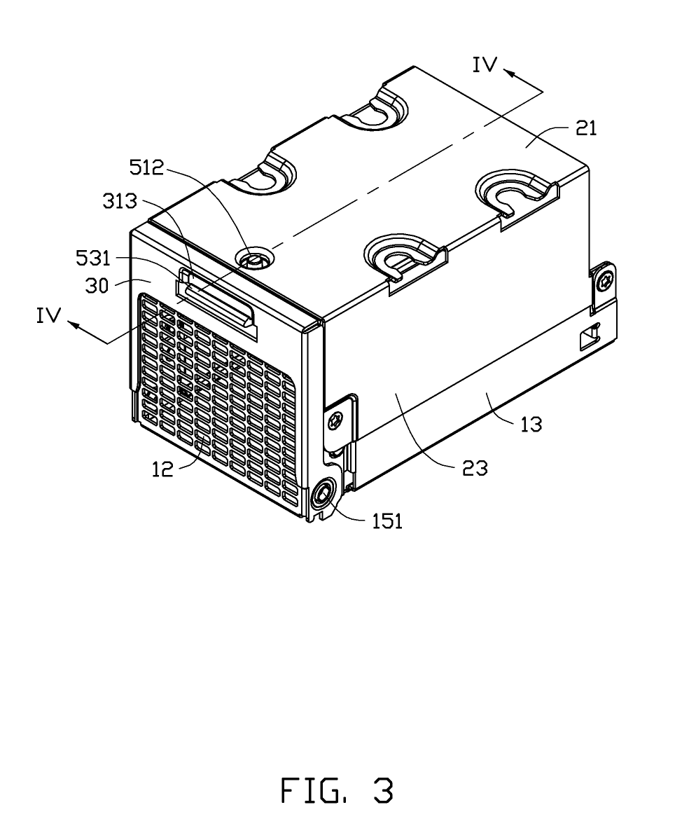

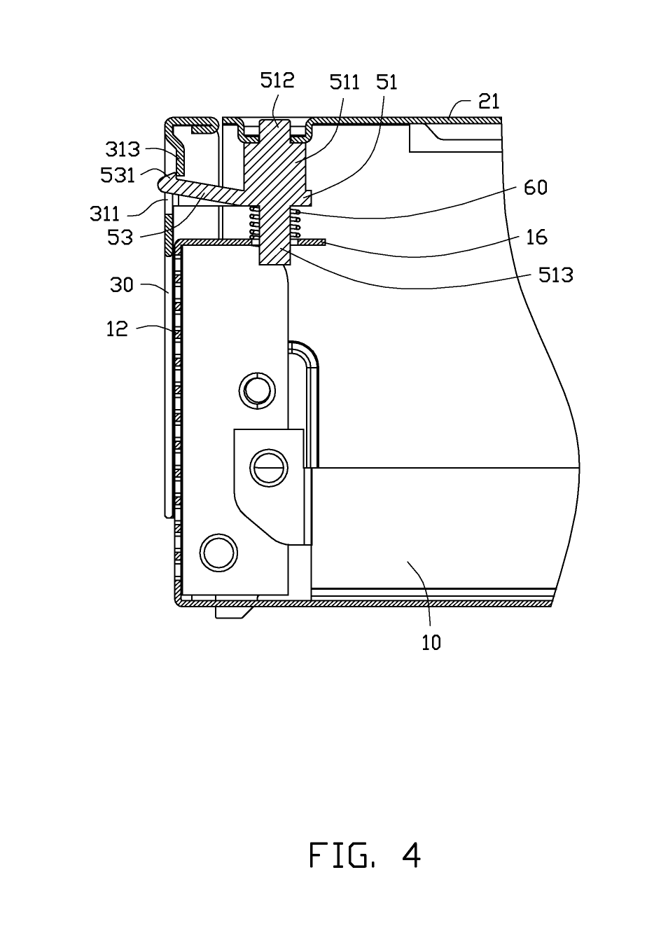

FIG. 3 and FIG. 4 show that in assembly, the resilient member 60 is placed on the holding plate 16. The positioning post 513 is inserted through the resilient member 60 and the receiving hole 161. The covering member 20 is coved to the chassis 10, with the pressing portion 512 extending out of the through hole 211. The sidewall 23 is secured to the flange 15 by riveting, soldering, or other securing methods. The covering member 20 covers the chassis 10. The top wall 21 is substantially parallel to the holding plate 16. A first end of the resilient member 60 abuts a bottom surface of the holding piece 51, and a second end of the resilient member 60 abuts the holding plate 16. The limiting post 511 is located between the top wall 21 and the holding piece 51. The pressing portion 512 is pressed to slide the latching member 50 relative to the chassis 10 and the covering member 20 up and down. The pivoting shaft 151 is inserted through the pivoting hole 331, to rotatably mount the rotating arm 33 to the flange 15. In this position, the resilient member 60 and the latching member 50 is in an initial position.

In assembly of the handle 30, the handle 30 is rotated towards the holding plate 16, until the handle 30 is blocked by the hook 531. The handle 30 is further rotated to elastically deform the resilient piece 53 downwards. The resilient piece 53 extends in the latching slot 311. The resisting arm 55 is elastically deformed by the mounting plate 31 and exerts elastic force to resist the mounting plate 31. The handle 30 is released, the resilient piece 53 rebounds to latch the hook 531 in the recess portion 313. In this position, the handle 30 is in a closed position.

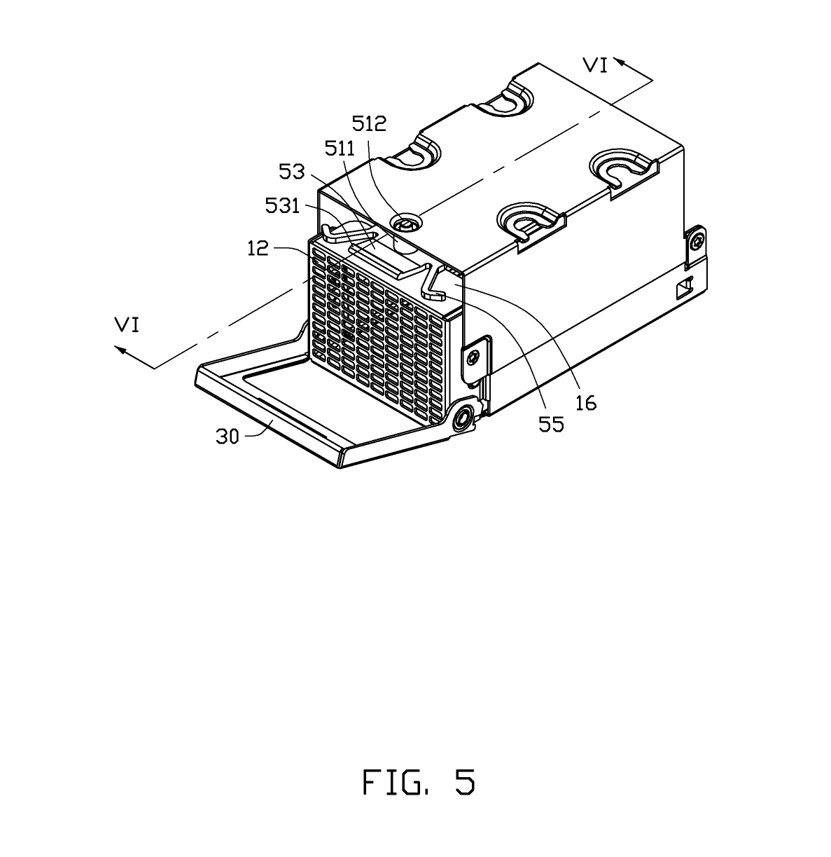

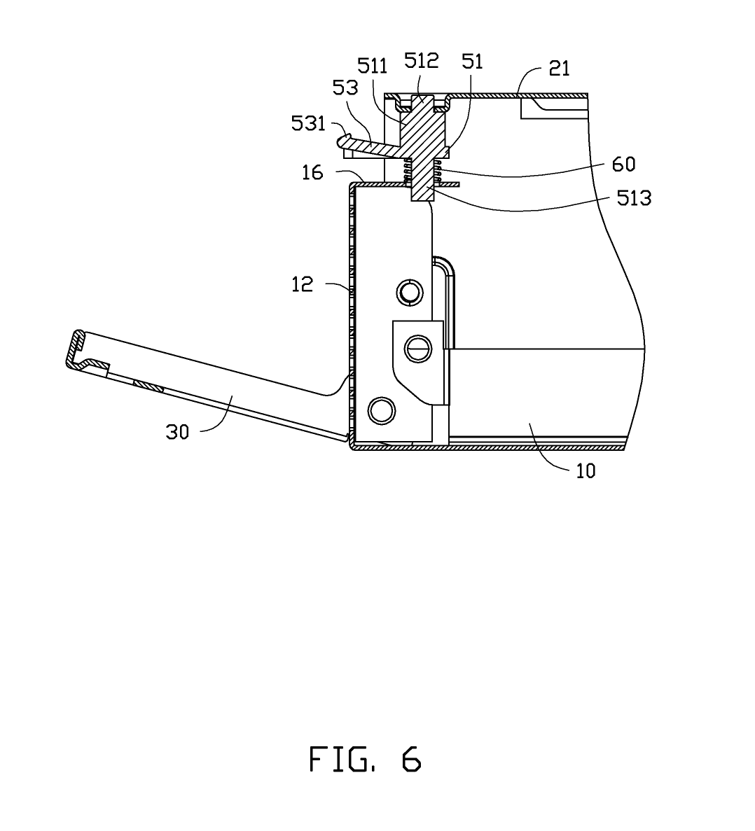

FIG. 5 and FIG. 6 show that when the handle 30 is needed to open, the pressing portion 512 is pressed downwards to move the latching member 50 downwards. The resilient member 60 is elastically deformed. The hook 531 disengages from the recess portion 313 and is aligned with the latching slot 311. The resisting arm 55 rebounds to extend the mounting plate 31 outwards, allowing the hook 531 to disengage from the latching slot 311. In this position, the handle 30 is opened to locate in an open position. The pressing portion 512 is released, the resilient member 60 rebounds to extend the latching member 50 in the initial position.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An electronic device enclosure, comprising:
a chassis;
a covering member secured to the chassis and covering the chassis;
a handle rotatably mounted to the chassis; and
a latching member slidably mounted between the chassis and the covering member and comprising a hook, a resisting arm, and a pressing portion;
wherein the pressing portion extends out of the covering member; the handle defines a latching slot; the handle is rotatable between an open position and a closed position; when the handle is in the closed position, the hook extends out of the latching slot and is engaged with the handle, the pressing portion is operable to be pressed to slide the latching member relative to the chassis to disengage the hook from the latching slot, and the resisting arm is elastically deformed to resist the handle; and when the handle is in the open position, the hook is disengaged from the latching slot, the pressing portion is operable to be pressed to slide the latching member relative to the chassis; and when the hook is disengaged from the latching slot, the resisting arm rebounds to rotate the handle from the closed position to the open position.

2. The electronic device enclosure of claim 1, further comprising a resilient member, wherein the latching member further comprises a holding piece and a resilient piece; the resisting arm and the resilient piece extend from the holding piece; the hook extends from a distal end of the resilient piece; and the resilient member is secured between the holding piece and the chassis.

3. The electronic device enclosure of claim 2, wherein the latching member further comprises a limiting post extending from the holding piece; the pressing portion is located on the limiting portion; the covering member defines a through hole; and the pressing portion extends out of the through hole.

4. The electronic device enclosure of claim 3, wherein the covering member comprises a top wall and a sidewall; the chassis comprises a bottom plate, a side plate, and a holding plate, and the bottom plate is substantially parallel to the holding plate; the top wall is substantially parallel to top plate; the sidewall is secured to the side plate; and a first end of the resilient member abuts the holding plate, and a second end of the resilient member abuts the resilient piece.

5. The electronic device enclosure of claim 4, wherein the limiting post is located between the top wall and the resilient piece.

6. The electronic device enclosure of claim 4, wherein the latching member further comprises a positioning post extending from the resilient piece, the holding plate defines a receiving hole, and the post extends through the resilient member and is slidably received in the receiving hole; and the positioning post and the limiting post are located on opposite two sides of holding piece.

7. The electronic device enclosure of claim 6, wherein the handle further comprises a mounting plate and a rotating arm connected to the mounting plate, the rotating arm is rotatably mounted to the chassis, and the latching slot is defined in the mounting plate; the mounting plate further defines a recess portion communicated with the latching slot, and the hook extends out of the latching slot and engages in the recess portion.

8. The electronic device enclosure of claim 2, wherein a cutout is defined between the resilient piece and the resisting arm, and the cutout receives the resisting arm when the resisting arm is elastically deformed.

9. The electronic device enclosure of claim 2, wherein the resilient piece extends slantingly from the holding piece.

10. The electronic device enclosure of claim 1, wherein the resisting arm is substantially “L” shaped.

11. An electronic device enclosure, comprising:
a chassis;
a covering member secured to the chassis and covering the chassis;
a handle rotatably mounted to the chassis; and
a latching member slidably mounted between the chassis and the covering member and comprising a hook, a resisting arm, and a pressing portion;
wherein the pressing portion extends out of the covering member; the handle defines a latching slot; the hook extends out of the latching slot and is engaged with the handle; the resisting arm is elastically deformed to resist the handle; the pressing portion is operable to be pressed to slide the latching member relative to the chassis to disengage the hook from the latching slot; and when the hook is disengaged from the latching slot, the resisting arm rebounds to rotate the handle, so as to open the handle.

12. The electronic device enclosure of claim 11, further comprising a resilient member, wherein the latching member further comprises a holding piece and a resilient piece; the resisting arm and the resilient piece extend from the holding piece; the hook extends from a distal end of the resilient piece; and the resilient member is secured between the holding piece and the chassis.

13. The electronic device enclosure of claim 12, wherein the latching member further comprises a limiting post extending from the holding piece; the pressing portion is located on the limiting portion; the covering member defines a through hole; and the pressing portion extends out of the through hole.

14. The electronic device enclosure of claim 13, wherein the covering member comprises a top wall and a sidewall; the chassis comprises a bottom plate, a side plate, and a holding plate, and the bottom plate is substantially parallel to the holding plate; the top wall is substantially parallel to top plate; the sidewall is secured to the side plate; and a first end of the resilient member abuts the holding plate, and a second end of the resilient member abuts the resilient piece.

15. The electronic device enclosure of claim 14, wherein the limiting post is located between the top wall and the resilient piece.

16. The electronic device enclosure of claim 14, wherein the latching member further comprises a positioning post extending from the resilient piece, the holding plate defines a receiving hole, and the post extends through the resilient member and is slidably received in the receiving hole; and the positioning post and the limiting post are located on opposite two sides of holding piece.

17. The electronic device enclosure of claim 16, wherein the handle further comprises a mounting plate and a rotating arm connected to the mounting plate, the rotating arm is rotatably mounted to the chassis, and the latching slot is defined in the mounting plate; the mounting plate further defines a recess portion communicated with the latching slot, and the hook extends out of the latching slot and engages in the recess portion.

18. The electronic device enclosure of claim 12, wherein a cutout is defined between the resilient piece and the resisting arm, and the cutout receives the resisting arm when the resisting arm is elastically deformed.

19. The electronic device enclosure of claim 12, wherein the resilient piece extends slantingly from the holding piece.

20. The electronic device enclosure of claim 11, wherein the resisting arm is substantially “L” shaped.
